(19) United States
(12) Patent Application Publication
(10) Pub. No.: US 2014/0122003 A1
(43) Pub. Date: May 1, 2014

(54) PREDICTION METHOD FOR SUN-TRACKING TYPE PHOTOVOLTAIC SYSTEM

(71) Applicant: National Taiwan University, Taipei (TW)

(72) Inventors: Joe Air Jiang, Taipei (TW); Kun Chang Kuo, Taipei City (TW); Jen Cheng Wang, New Taipei City (TW); Yu Li Su, New Taipei City (TW); Jui-Jen Chou, Taipei (TW)

(21) Appl. No.: 13/928,032

(22) Filed: Jun. 26, 2013

(30) Foreign Application Priority Data
Nov. 1, 2012 (TW) 101140563

(51) Int. Cl. G01R 21/133

(52) U.S. Cl. CPC G01R 21/133
USPC 702/61

(57) ABSTRACT

A method for predicting power generation for a sun-tracking type photovoltaic system. A calculating device may perform the prediction method and may comprise the steps of: forming a mathematical relationship that relates the variation in sunlight incident angle of powers for sun-tracking type and fixed-type photovoltaic systems to at least one electrical characteristic of the photovoltaic system; accumulating ratios between the power production rate of the sun-tracking type photovoltaic system and the fixed-type photovoltaic system; and according to a predetermined cost estimation structure, providing an analysis for determining whether a sun-tracking type photovoltaic system should be installed.

### CROSS-REFERENCE TO RELATED APPLICATION(S)

This application claims priority to Taiwan Patent Application No. 101140563, filed on Nov. 1, 2012, the disclosure of which is hereby incorporated by reference in its entirety.

### FIELD OF THE DISCLOSURE

The present disclosure generally relates to a prediction method of power generation of a photovoltaic system. More specifically, certain embodiments of the disclosure relate to prediction methods for the power generation of mounting a sun-tracking type or fixed-type photovoltaic system.

### BACKGROUND OF THE DISCLOSURE

Photovoltaic systems are attracting significant attention in both industry and academia. There is a great deal of interest in the various stages of producing photovoltaic systems, including raw materials, chips, solar cell modules, and systems. A substantial industry has formed around this technology. One important characteristic of photovoltaic systems is the conversion rate or power of performing photoelectric conversion. The conversion rate is the rate at which the energy of sunlight is converted to electrical current. It may be desirable to accurately predict this characteristic. Being able to do so would allow one to better determine the costs and benefits of mounting a particular photovoltaic system before significant capital has been invested.

Generally, one difference between sun-tracking type and fixed-type photovoltaic systems is that in sun-tracking type photovoltaic systems, the inclined angle of the solar cell modules and the sunlight incident angle are periodically adjusted to make the sunlight incident vertically onto the solar cell modules. These adjustments allow the photovoltaic system to achieve higher power. In contrast, in fixed-type photovoltaic systems, the inclined angle of the solar cell modules is fixed. As one of ordinary skill in the art would appreciate, the power of a fixed-type photovoltaic system may be affected by the current sunlight incident angle.

The ability to accurately predict the conversion rate of a photovoltaic system may be affected by environmental factors. Such factors may include shading from clouds and sunlight duration. The inaccuracy of the prediction may be high. Currently, there is some experimental data provided by various research centers for predicting the benefit of sun-tracking type photovoltaic systems. However, such experimental data is challengeable based on their short observation periods and/or unexamined accuracy. Accordingly, there is a need to develop a solution for accurately predicting and comparing the performance of sun-tracking type and fixed-type photovoltaic systems.

### SUMMARY OF THE DISCLOSURE

The present disclosure relates, in some embodiments, to a prediction method for power generation for mounting a sun-tracking type or a fixed-type photovoltaic system. A mathematical relationship may be formed between the variation in power of sun-tracking type and fixed-type photovoltaic systems and the sunlight incident angle according to an electrical character of a solar cell module. According to the mathematical relationship, a ratio between the accumulated powers of sun-tracking type and fixed type photovoltaic systems in a predetermined period may be obtained. This ratio may be used for predicting the benefit of mounting a sun-tracking type photovoltaic system.

Some embodiments of the disclosure relate to a prediction method for power generated by a sun-tracking type system or a fixed-type photovoltaic system that reduces or eliminates the effect of environmental factors. As a result, a more accurate prediction may be obtained.

According to some embodiments of the present disclosure, a prediction method for the power generation of sun-tracking type photovoltaic system may be executed in a calculating device. The prediction method executed in the calculating device may comprise: forming a mathematical relation that relates a variation in a sunlight incident angle between powers for sun-tracking type and fixed-type photovoltaic systems according to at least one electrical characteristic of a solar cell module; sequentially substituting a plurality of values of the sunlight incident angle at a plurality of sampling times corresponding to a predetermined period in the mathematical relation; determining, in the calculating device, the ratio between the power of the sun-tracking type photovoltaic system to the power of the fixed-type photovoltaic system; and performing a calculation according to a predetermined capital structure that provides an analysis for determining if it is worthy to mount a sun-tracking photovoltaic system, wherein performing further comprises mounting the sun-tracking photovoltaic system as indicated by the calculation.

Both the sun-tracking type and fixed-type photovoltaic systems considered in the present disclosure may comprise a solar cell module for performing photoelectric conversion. For example, the solar cell module may be, but is not limited to, a monocrystalline silicon solar cell module, a polycrystalline silicon solar cell module, or a amorphous silicon solar cell module. As another example, the sun-tracking type photovoltaic system may be, but is not limited to, a specific two-axis sun-tracking type photovoltaic system.

As one of ordinary skill in the art may appreciate, to reduce or eliminate effects from the changing sunlight incident angle, the predetermined period may preferably be long enough for Earth to orbit the ecliptic orbit one or multiple cycles (e.g., one year.) Additionally, the density of incident angle sample times in the predetermined period may be relative to the accuracy of the prediction. For example, the more concentrated the sample times, the more values of the sunlight incident angle may be accumulated. Accordingly, the more accurate the resulting prediction. However, the calculation process may be complex. As an example, according to an embodiment of the present disclosure, the values of the sunlight incident angle substituted into the mathematical relationship for accumulation may be at times that are fifteen-minutes apart.

A prediction method for power generation of sun-tracking type photovoltaic system in the present disclosure may involve a mathematical relationship. The mathematical relationship may relate the powers of the sun-tracking type and fixed-type photovoltaic systems to the sunlight incident angle. Preferably, the mathematical relation may comprise two physical quantities identified by the varying sunlight incident angle. More specifically, according to one embodiment of the present disclosure, the first physical quantity may be an open-circuit voltage and the second physical quantity may be a short-circuit current. The quantities may be electrical characters, open-circuit voltage equation, and short-circuit current equation of the solar cell module. For example, the mathematical relation may be:

P(θ)/P(0)=V_{OC}(θ)·I_{SC}(θ)/V_{OC}(0)·I_{SC}(0).

According to embodiments of the present disclosure, two values of the sunlight incident angle at each sampling time may be exemplarily substituted into the mathematical relationship as the first and second physical quantities. One may be the value of the sunlight incident angle relative to a fixed-type photovoltaic system, and the other may be the value of the sunlight incident angle relative to a sun-tracking type photovoltaic system. In the sun-tracking type photovoltaic system, the surface angle of the solar cell module receiving the incident sunlight and the current sunlight incident angle may periodically change. Thus, preferably, the sunlight incident angle relative to a sun-tracking type photovoltaic system may be zero degrees.

Therefore, as mentioned above, the prediction method for power generation of a sun-tracking type photovoltaic system according to the present disclosure may reduce or eliminate the effect of various environmental factors. Such factors may include the sunlight incident angle, climate, shading from clouds, etc. The result is a more accurate and objective prediction resulting from the ratio between the power of the sun-tracking type photovoltaic system and the power of the fixed-type photovoltaic system. Said ratio may be calculated based on a mathematical relationship pertaining to an electrical characteristic of a solar cell module.

### BRIEF DESCRIPTION OF THE DRAWINGS

Various objects and advantages of the present disclosure will be more readily understood from the following detailed description when read in conjunction with the appended drawing, in which:

FIG. 1 depicts a diagram showing a celestial sphere comprising an exemplary sunlight incident angle θ;

FIG. 2 depicts a process flow of an embodiment of a prediction method of power generation of sun-tracking type photovoltaic system according to an embodiment of the present disclosure;

FIG. 3 depicts a perspective view of a calculating device performing a prediction method of power generation of sun-tracking type photovoltaic system according to an embodiment of the present disclosure;

FIG. 4 depicts a chart of the values of the sunlight incident angle at North 24.93, East 121.22 collected according to an embodiment of the present disclosure;

FIG. 5(a) depicts a perspective view showing that the sunlight incident angle θ of a sun-tracking type photovoltaic system equals that of a fixed-type photovoltaic system when a sun-tracking type photovoltaic system does not adjust its tilted angle according to an embodiment of the present disclosure;

FIG. 5(b) depicts a perspective view of the sunlight incident angle θ of a sun-tracking type photovoltaic system when the sun-tracking type photovoltaic system adjusts its tilted angle according to an embodiment of the present disclosure; and

FIG. 6 depicts the variation of the ratio between the powers of the sun-tracking type and fixed-type photovoltaic systems calculated by the calculating device and presented in three-dimensions according to an embodiment of the present disclosure.

### DETAILED DESCRIPTION

For a more complete understanding of the present disclosure and its advantages, reference is now made to the following description taken in conjunction with the accompanying drawings. One of ordinary skill in the art will understand other varieties for implementing example embodiments, including those described herein. The drawings are not limited to specific scale and similar reference numbers are used for representing similar elements. As used in the disclosure and the appended claims, the terms “example embodiment,” “exemplary embodiment,” and “present embodiment” do not necessarily refer to a single embodiment, although it may, and various example embodiments may be readily combined and interchanged, without departing from the scope or spirit of the present disclosure. Furthermore, the terminology as used herein is for the purpose of describing example embodiments only and is not intended to be a limitation of the disclosure. In this respect, as used herein, the term “in” may include “in” and “on”, and the terms “a”, “an”, and “the” may include singular and plural references. Furthermore, as used herein, the term “by” may also mean “from”, depending on the context. Furthermore, as used herein, the term “if” may also mean “when” or “upon”, depending on the context. Furthermore, as used herein, the words “and/or” may refer to and encompass any and all possible combinations of one or more of the associated listed items.

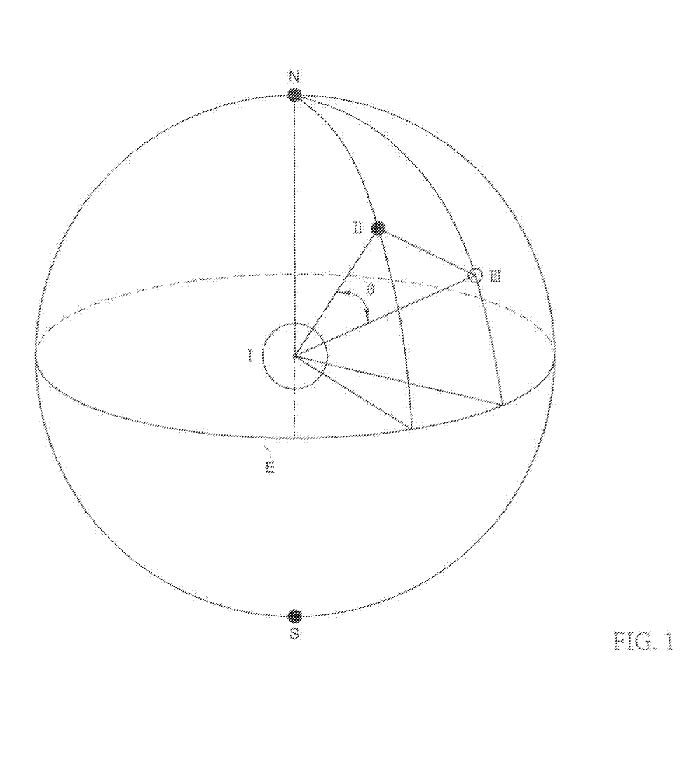

FIG. 1 depicts a celestial sphere comprising an exemplary sunlight incident angle θ. FIG. 1 further depicts Equator E of celestial sphere, north pole N of celestial sphere, and south pole S of celestial sphere. One of ordinary skill in the art would appreciate that FIG. 1 denotes the relative positions between Earth I, Zenith II, and Sun III. One of ordinary skill in the art would further appreciate from FIG. 1 that the sunlight incident angle θ may change as Earth orbits in its elliptical orbit. Accordingly, as time goes by, the angle θ would be different at each sampling time.

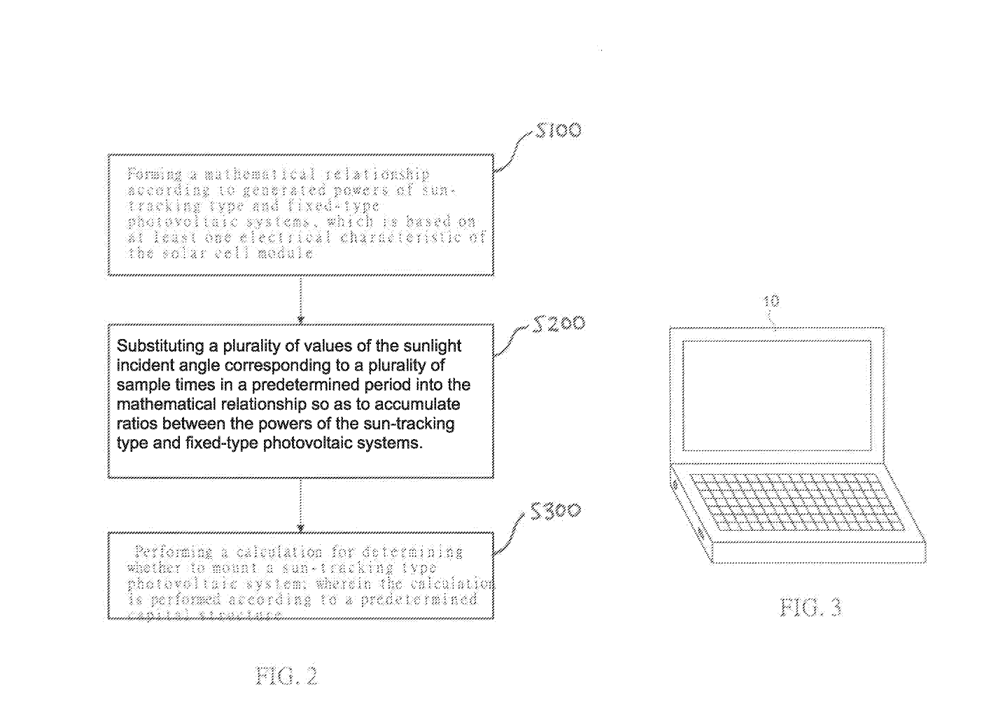

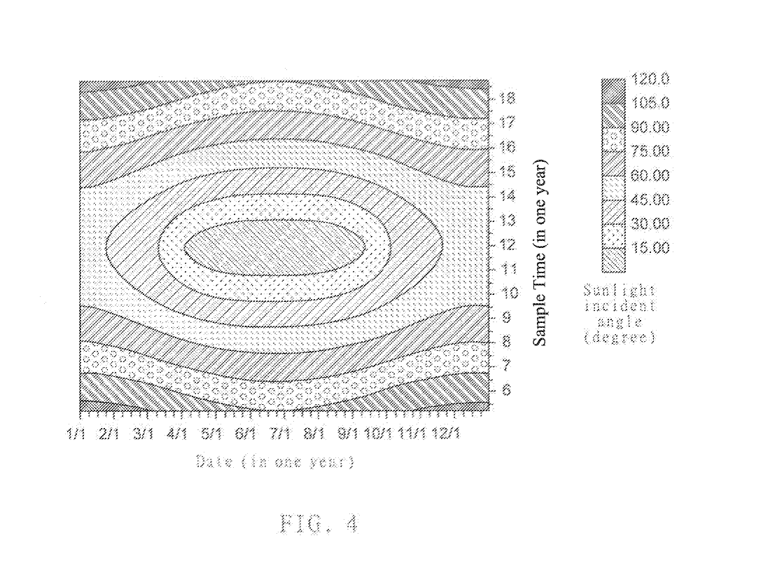

FIG. 2 depicts a process flow of a prediction method for the power generation of a sun-tracking type photovoltaic system according to an embodiment of the present disclosure. Here, a solar cell module may be chosen from, but is not limited to, a monocrystalline silicon solar cell module, a polycrystalline silicon solar cell module, and a amorphous silicon solar cell module. The prediction method of the present embodiment may be applied in a calculating device which performs recording, calculation, and/or analysis actions. The calculating device for example may comprise a calculating module, a storage module and operationally a further linking module and/or report module. The storage module may store the results generated during the sequential substitution or calculation which is carried out by the calculating module. The mathematical relation as mentioned is formed in the calculating module with the assistance of the linking module which may access a database which collects all the values of the sunlight incident angle during the predetermined period or the storage module which stores these values. The report module may provide a human-machine interface for reporting the result of the calculation which may comprise determining if mounting the sun-tracking photovoltaic system as indicated by the calculation. Here, calculating device 10 is an exemplary computer. Referring back to FIG. 2, at action S100, calculating device 10 may form a mathematical relationship according to the generated powers of sun-tracking type and fixed-type photovoltaic systems. This mathematical relationship may be based on at least one electrical characteristic of the solar cell module. The mathematical relationship relates to the sunlight incident angle. In light of the solar cell module in the sun-tracking type or fixed-type photovoltaic systems performing photoelectric conversion, the power, voltage, and current of the solar cell module may be defined by:

P=V·I

Therefore, the mathematical relationship relating to the power is preferably derived from the electrical characteristics of the voltage and current of the solar cell module. Examples of such include the open-voltage equation, short-current equation, etc.

The open-voltage equation when the solar cell is not loaded may be defined by Equation (1):

V_{OC}=(nkT/q)ln[(I_{g}+Iₛₐₜ)/Iₛₐₜ] (1)

In Equation (1), open-voltage is denoted by V_{OC}, ideality factor is denoted by n, electric charge is denoted by q (C), Boltzmann constant is denoted by k (eVKC⁻¹), temperature is denoted by T, photocurrent is denoted by I_{g} (A), and reverse saturation current is denoted by Iₛₐₜ (A).

The irradiance intensity of the incident sunlight may decrease along with the increasing sunlight incident angle to make the photocurrent I_{g} decrease. Thus, the photocurrentI_{g} in the Equation (1) may be replaced by the cosine component of the photocurrent I_{g(0)} relating to the sunlight incident angle θ. Accordingly, Equation (2) may be obtained:

V_{OC}(θ)=(nkT/q)ln[(I_{g(0)}·cos(θ)+Iₛₐₜ)/Iₛₐₜ] (2)

In Equation (2), the photocurrent when the sunlight incident angle is equal to zero and is denoted by I_{g(0)} (A).

Therefore, the ratio between V_{OC}(θ) and V_{OC}(0) may be expressed by Equation (3):

V_{OC}(θ)/V_{OC}(0)=ln[(I_{g(0)}cos(θ)+Iₛₐₜ)/Iₛₐₜ]/ln[(I_{g(0)}+Iₛₐₜ)/Iₛₐₜ] (3)

Equation (3) is an equation derived from the variation in sunlight incident angle for defining the relationship between the open-voltages of sun-tracking type and fixed-type photovoltaic systems. In Equation (3), the open-voltage of the fixed-type photovoltaic system is denoted by V_{OC}(θ), and the open-voltage of the sun-tracking type photovoltaic system is denoted by V_{OC}(0).

Further, when the output voltage of a solar cell module equals to zero, the short-current may be defined by Equation (4).

I_{SC}=I_{g}−Iₛₐₜ{exp[q(I_{SC}R_{S})/nkT]−1} (4)

In Equation (4), resistance in serial connection is denoted by Rs (Ω).

Similarly, the irradiance intensity of the incident sunlight may decrease along with the increasing sunlight incident angle to make the photocurrent I_{g} decrease. Thus, I_{SC} and I_{g} in Equation (4) may be replaced by cosine components relating to the sunlight incident angle θ. Accordingly, Equation (5) may be derived from Equation (4):

I_{SC}(θ)=I_{g(0)}·cos(θ)=Iₛₐₜ{exp[q(I_{SC}R_{S})/nkT]−1} (5)

Therefore, the ratio between I_{SC}(θ) and I_{SC}(0) may be expressed by Equation (6):

I_{SC}(θ)/I_{SC}(0)={I_{g(0)}·cos(θ)−Iₛₐₜ{exp[q(I_{SC}(θ)R_{S})/nkT]−1}}/{I_{g(0)}−Iₛₐₜ{exp[q(I_{SC}(0)R_{S})/nkT]−1}} (6)

Equation (6) is an equation derived from the variation in sunlight incident angle to define the relationship between the short-currents of sun-tracking type and fixed-type photovoltaic systems. In Equation (6), the short-current of the fixed-type photovoltaic system is denoted by I_{SC}(θ), and the short-current of the sun-tracking type photovoltaic system is denoted by I_{SC}(0).

As one of ordinary skill in the art would appreciate, one may assume that the power at maximum power point (mpp) relates to the sunlight incident angle θ. The ratio between the powers of the sun-tracking type and fixed-type photovoltaic systems may be expressed by Equation (7):

P(θ)/P(0)=Vₘₚₚ(θ)·Iₘₚₚ(θ)/Vₘₚₚ(0)·Iₘₚₚ(0) (7)

The voltage and current at the maximum power point of the fixed-type photovoltaic system is denoted by Vₘₚₚ(θ) and Iₘₚₚ(θ) respectively, and the voltage and current at the maximum power point of the sun-tracking type photovoltaic system is denoted by Vₘₚₚ(0) and Iₘₚₚ(0) respectively.

According to other related research, the products of the open-voltage or short-current multiplied by a constant may approach the voltage or current at the maximum power point. For example:

Vₘₚₚ(θ)=0.81×V_{OC}(θ);

Vₘₚₚ(0)=0.81×V_{OC}(0);

Iₘₚₚ(θ)=0.93×I_{SC}(θ);

Iₘₚₚ(0)=0.93×I_{SC}(0)°

Thus, the calculating device 10 may build up the mathematical relationship as follows:

P(θ)/P(0)=V_{OC}(θ)·I_{SC}(θ)/V_{OC}(0)·I_{SC}(0)

The aforementioned mathematical relationship is derived from the open-voltage V_{OC} and short-current I_{SC}. The resulting relationship between the powers of sun-tracking type and fixed-type photovoltaic systems with the sunlight incident angle may reduce or eliminate the effects of environmental factors to improve the accuracy of prediction.

Referring again to FIG. 2, action S200 may involve sequentially substituting, in the calculating device, a plurality of values of the sunlight incident angle at a plurality of sampling times corresponding to a predetermined period into the mathematical relation. This may accumulate ratios between the powers of the sun-tracking type and fixed-type photovoltaic systems. Here, a proper mathematical operator may be used for calculation, such as but not limited to Σ or integral.

To reduce or eliminate the effect of the changing sunlight incident angle upon the prediction, the predetermined period may preferably be long enough for Earth to orbit its elliptical orbit one or multiple cycles (e.g., one year.) Further, the density of sampling times in the predetermined period is relevant to the accuracy of the prediction. For example, the more concentrated the sampling times, more values of the sunlight incident angle are available for accumulation, and the more accurate the prediction. However, the calculation process may be complex. As an example, according to an embodiment of the present disclosure, the values of the sunlight incident angle substituted by the calculating device 10 into the mathematical relationship for accumulation may be separated by fifteen-minute intervals. This corresponds to the period for adjustment of the tilted angle for the sun-tracking type photovoltaic system 2. The mathematical relation used for accumulation may be as follows. One of ordinary skill in the art would appreciate that the adjustment period as well as the interval between two adjacent sampling times is not limited to the example given here.

$$\frac{{\int }_{time} \begin{matrix}P ( θ ) d t \\ interval\end{matrix}}{{\int }_{time} \begin{matrix}P ( 0 ) d t \\ interval\end{matrix}} = \frac{{\int }_{time} \begin{matrix}v ( θ ) I ( θ ) d t \\ interval\end{matrix}}{{\int }_{time} \begin{matrix}V ( 0 ) I ( 0 ) d t \\ interval\end{matrix}} = \frac{{\sum }_{n = 1}^{365} {\sum }_{Q = 1}^{96} {V}_{OC} ( θ ) \cdot Isc ( θ )}{{\sum }_{n = 1}^{365} {\sum }_{Q = 1}^{96} {V}_{OC} ( 0 ) \cdot Isc ( 0 )}$$

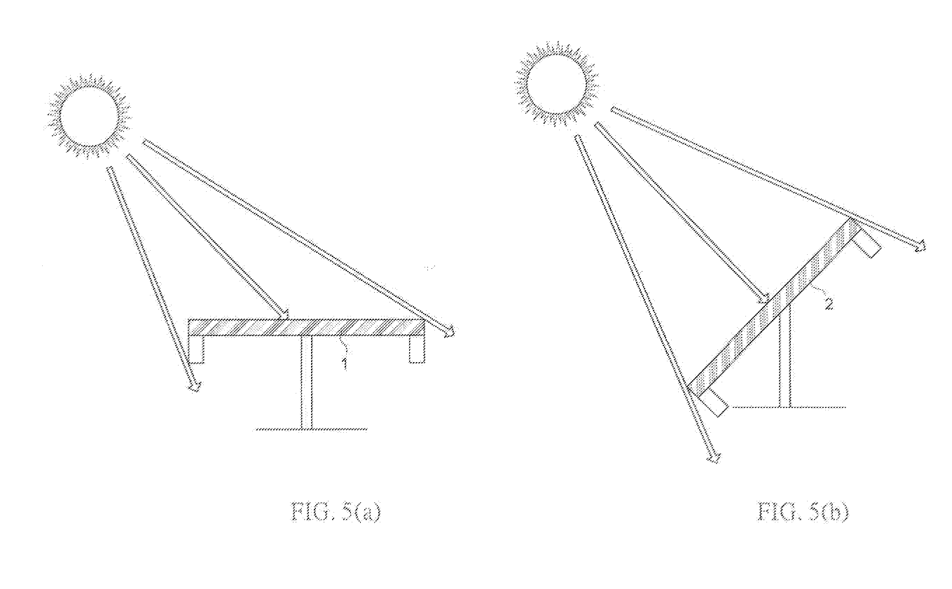

FIG. 4 depicts a chart of the values of the sunlight incident angle at North 24.93, East 121.22. FIG. 5(a) depicts a perspective view of the sunlight incident angle θ of a sun-tracking type photovoltaic system equal to that of a fixed-type photovoltaic 1 system when the sun-tracking type photovoltaic system does not adjust its tilted angle. FIG. 5(b) depicts a perspective view of the sunlight incident angle θ of a sun-tracking type photovoltaic system 2 mounted as indicated by the calculations above. As shown in FIG. 4, from the incident angle defined by the relative positions of the Sun and the Earth at each sampling time, the calculating device 10 may obtain the value of the sunlight incident angle of the fixed-type photovoltaic system 1. Then, the values of the sunlight incident angle θ at the sampling times may be sequentially substituted into the open-voltage V_{OC}(θ) and short-current I_{SC}(θ) of the mathematical relation. The sun-tracking type photovoltaic system 2 would adjust the tilted angle of the incident surface of the solar cell module therein and change the sunlight incident angle. Thus, the value of the sunlight incident angle for the sun-tracking type photovoltaic system 2 may preferably be zero. Thus, zero degrees may be substituted into the mathematical relationship for replacing the sunlight incident angle of the sun-tracking type photovoltaic system 2.

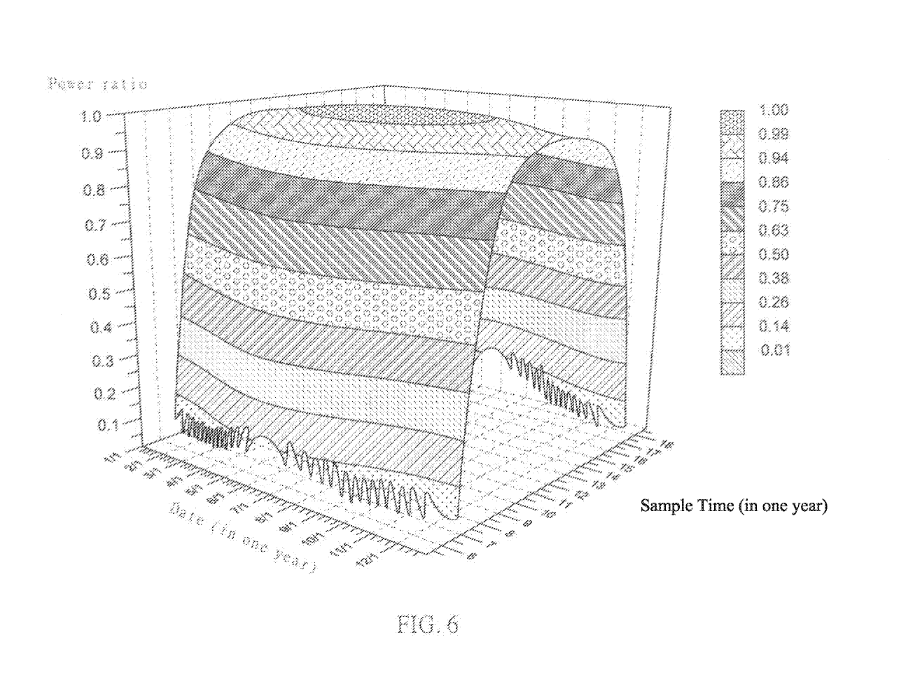

FIG. 6 depicts the variation of the ratio between the powers of the sun-tracking type and fixed-type photovoltaic systems calculated by the calculating device 10 and presented in three-dimensions.

According to embodiments of the present disclosure, the predicted benefit for mounting a sun-tracking type photovoltaic system at North 24.92 is about 19.39%. Empirically, the benefit for mounting a sun-tracking type photovoltaic system at North 24.92 is 16.74%. The error in each month of the year is within 5%. As one of ordinary skill in the art would appreciate, the prediction may be accurate and objective. Please refer to the table as follows:

| | Benefit | | Prediction quality | |
|---|---|---|---|---|
| | Ideal value | Examination | Error | Accuracy |
| Month | (%) | (%) | (%) | (%) |
| January | 22.05 | 22.53 | 0.48 | 102.18 |
| February | 19.29 | 18.32 | 0.97 | 94.97 |
| March | 16.44 | 15.23 | 1.21 | 92.64 |
| April | 15.31 | 14.69 | 0.62 | 95.95 |
| May | 14.93 | 13.78 | 1.15 | 92.30 |
| June | 14.16 | 14.31 | 0.15 | 101.06 |
| July | 14.04 | 14.86 | 0.82 | 105.84 |
| August | 14.65 | 14.41 | 0.24 | 98.36 |
| September | 15.95 | 15.84 | 0.11 | 99.31 |
| October | 18.03 | 16.83 | 1.20 | 93.34 |
| November | 21.47 | 20.06 | 1.41 | 93.43 |
| December | 23.09 | 25.09 | 2.00 | 108.66 |
| Annual average | 19.39 | 16.74 | 0.86 | 98.17 |
| Standard deviation | 3.26 | 3.48 | 0.52 | 5.16 |

Referring again to FIG. 2, action S300 may involve performing, in the calculating device 10, a calculation according to a predetermined capital structure that provides an analysis for determining whether to mount a sun-tracking photovoltaic system. Here, the predetermined capital structure may comprise considerations such as the price, mounting cost, power consumption, maintenance fee, and other items of the sun-tracking type photovoltaic system and fixed-type photovoltaic system. Preferably, the items of the capital structure may be open for customization, which may require allowing for the addition or deletion of any consideration therein.

As one of ordinary skill in the art would appreciate, the prediction method of power generation for a sun-tracking type photovoltaic system according to the present disclosure may reduce or eliminate the effects of various environmental factors. Such factors may include sunlight incident angle, climate, shading from clouds, etc. The result may be a more accurate and objective prediction of the ratio between the powers of the sun-tracking type photovoltaic system and fixed-type photovoltaic systems, wherein the ratio may be calculated based on a mathematical relationship derived from an electrical characteristic of a solar cell module.

Realizations in accordance with the present disclosure have been described in the context of particular embodiments. These embodiments are meant to be illustrative and not limiting. Many variations, modifications, additions, and improvements are possible. Accordingly, plural instances may be provided for components described herein as a single instance. Structures and functionality presented as discrete components in the exemplary configurations may be implemented as a combined structure or component. These and other variations, modifications, additions, and improvements may fall within the scope of the invention as defined in the claims that follow.

While various embodiments in accordance with the principles disclosed herein have been described above, it should be understood that they have been presented by way of example only, and not limitation. Thus, the breadth and scope of this disclosure should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the embodiment(s) set out in any claims that may issue from this disclosure. Specifically and by way of example, although the headings refer to a “Field of the Disclosure,” the claims should not be limited by the language chosen under this heading to describe the so-called field. Further, a description of a technology in the “Background” is not to be construed as an admission that certain technology is prior art to any embodiment(s) in this disclosure. Neither is the “Summary” to be considered as a characterization of the embodiment(s) set forth in issued claims. Furthermore, any reference in this disclosure to “invention” in the singular should not be used to argue that there is only a single point of novelty in this disclosure. Multiple embodiments may be set forth according to the limitations of the multiple claims issuing from this disclosure, and such claims accordingly define the embodiment(s), and their equivalents, that are protected thereby. In all instances, the scope of such claims shall be considered on their own merits in light of this disclosure, but should not be constrained by the headings set forth herein.

What is claimed is:

1. A prediction method for power generation of a sun-tracking type photovoltaic system, executable in a calculating device, comprising the steps of:
forming a mathematical relationship,
wherein the mathematical relationship relates a variation in a sunlight incident angle to power of a sun-tracking type photovoltaic system and power of a fixed-type photovoltaic system, and
wherein the mathematical relationship is formed according to at least one electrical characteristic of a solar cell module;
sequentially substituting a plurality of values into the mathematical relationship, and accumulating a plurality of ratios,
wherein the plurality of values are sunlight incident angles at a plurality of sampling times corresponding to a predetermined period, and
wherein the plurality of ratios are ratios between the power of the sun-tracking type photovoltaic system and the power of the fixed-type photovoltaic system; and
performing a calculation for determining whether to mount the sun-tracking photovoltaic system,
wherein the calculation is performed according to a predetermined capital structure.

2. The prediction method according to claim 1, wherein the mathematical relationship is formed based on a first physical quantity and a second physical quantity, wherein both the first physical quantity and the second physical quantity are identified by varying sunlight incident angles.

3. The prediction method according to claim 2, wherein the first physical quantity is an open-voltage current and the second physical quantity is a short-current.

4. The prediction method according to claim 3, wherein the at least one electrical characteristic comprises an equation of open-voltage for the solar cell module and an equation of the short-current for the solar cell module.

5. The prediction method according to claim 3, wherein the mathematical relationship is:
$$\frac{P ( θ )}{P ( 0 )} = \frac{{V}_{oc} ( θ ) \cdot {I}_{sc} ( θ )}{{V}_{oc} ( 0 ) \cdot {I}_{sc} ( 0 )} .$$

6. The prediction method according to claim 1, wherein each of the plurality of values comprises a first value and a second value, wherein the first value is the sunlight incident angle relative to the fixed-type photovoltaic system, and wherein the second value is the sunlight incident angle relative to the sun-tracking type photovoltaic system.

7. The prediction method according to claim 6, wherein the value of the sunlight incident angle relative to the sun-tracking type photovoltaic system is zero.

8. The prediction method according to claim 1, wherein the predetermined period is one year and the values of the plurality of sampling times are separated by fifteen-minute intervals.

9. The prediction method according to claim 1, wherein the performing a calculation for determining whether to mount the sun-tracking photovoltaic system further comprises mounting the sun-tracking photovoltaic system as indicated by the calculation.
